(19) United States
(12) Patent Application Publication
(10) Pub. No.: US 2016/0087234 A1
(43) Pub. Date: Mar. 24, 2016

(54) ORGANIC SOLAR CELL COMPRISING NANO-BUMP STRUCTURE AND MANUFACTURING METHOD THEREFOR

(71) Applicants: GLOBAL FRONTIER CENTER FOR MULTISCALE ENERGY SYSTEMS, Seoul (KR); SEOUL NATIONAL UNIVERSITY R & DB FOUNDATION, Seoul (KR)

(72) Inventors: Hyung-Jun SONG, Seoul (KR); Kinam JUNG, Seoul (KR); Gunhee LEE, Seoul (KR); Youngjun KO, Seoul (KR); Jong-Kwon LEE, Seoul (KR); Changhee LEE, Seoul (KR); Man Soo CHOI, Seoul (KR)

(21) Appl. No.: 14/891,024

(22) PCT Filed: Feb. 2, 2015
(86) PCT No.: PCT/KR2015/001056

§ 371 Date: Nov. 13, 2015

(30) Foreign Application Priority Data
Feb. 3, 2014 (KR) 10-2014-0012301

(51) Int. Cl. H01L 51/44; H01L 51/42

(52) U.S. Cl. CPC H01L 51/447; H01L 51/426; H01L 51/441; H01L 51/442; H01L 2251/301; H01L 2251/303; H01L 2251/308; H01L 2251/306; H01L 2251/305

(57) ABSTRACT

An organic photovoltaic cell is provided. The organic photovoltaic cell includes a first electrode layer formed on a substrate, metal nanoparticles bound to the surface of the first electrode layer, a hole transport layer formed on the metal nanoparticles to form a nano-bump structure together with the metal nanoparticles, a photoactive layer formed on the hole transport layer, and a second electrode layer formed on the photoactive layer. The nano-bump structure enhances plasmonic effects, leading to an increase in photocurrent. The photoactive layer has an uneven structure. This uneven structure allows the photoactive layer to absorb larger amount of light than an even structure does, leading to an improvement in the photovoltaic efficiency of the organic photovoltaic cell. In addition, the nano-bump structure can be formed by simple dry aerosol deposition without involving a complicated exposure or transfer process, contributing to a marked improvement in economic efficiency.

### BACKGROUND OF THE INVENTION

1. Field of the Invention

The present invention relates to an organic photovoltaic cell including a nano-bump structure and a method for fabricating same. More specifically, the present invention relates to an organic photovoltaic cell whose photovoltaic efficiency is improved by adopting a nano-bump structure that enhance plasmonic effects and light absorption efficiency, and a method for fabricating the organic photovoltaic cell.

2. Description of the Related Art

Rising oil prices are attributed to increasing global consumption of fossil fuels and a growing demand for alternative energy is attributed to environmental problems, such as global warming.

Solar cell technologies for producing electricity from sunlight as an unlimited energy source are attracting the most attention among various renewable energy technologies. Inorganic silicon solar cells accounting for the largest portion of the current solar cells are commercially available but require expensive raw materials and complicated fabrication processes, which are disadvantageous from the viewpoint of economic efficiency.

Under such circumstances, organic photovoltaic cells (OPVs) are gaining much attention as alternative inorganic silicon solar cells. Organic photovoltaic cells have many potential applications as next-generation solar cells due to their light weight, high flexibility, and low price. However, organic photovoltaic cells have relatively low power conversion efficiencies (PCEs) in comparison with inorganic silicon solar cells. For this reason, a further improvement in the performance of organic photovoltaic cells is needed for practical use.

Development of new active layer materials that are capable of absorbing light in a broad range of wavelengths, possess high carrier mobility, and have an appropriate optical band gap for an optimum open circuit voltage (Voc) is urgently needed to achieve higher efficiency of organic bulk hetero junction solar cells.

Many proposals have been made to improve the structural and optical properties of solar cells. For example, techniques have been proposed to improve the structural properties of a device associated with the interface between an electrode and an active layer or to enhance the optical properties (e.g., light absorption) of an active layer by inducing surface plasmons. These techniques are applicable irrespective of materials employed and are thus required to acquire high power conversion efficiency of organic photovoltaic cells.

The power conversion efficiency of organic bulk hetero junction solar cells is mainly determined by incident photon-to-current conversion efficiency, which can be represented by the product of light absorption efficiency and internal quantum efficiency. Accordingly, higher incident photon-to-current conversion efficiency is required to obtain higher power conversion efficiency. However, the trade-off between the light absorption efficiency and the internal quantum efficiency makes it difficult to increase the incident photon-to-current conversion efficiency. That is, an increase in the thickness of an active layer leads to low carrier mobility and therefore a decrease in internal quantum efficiency, which may decrease the power conversion efficiency despite increased light absorption. A method is thus needed to increase the light absorption of the active layer at the same thickness.

In an attempt to overcome such problems, a method is known in which nanoparticles or nanostructures are introduced to increase the intensity of light entering an active layer and to induce a longer propagation path of the light. Specifically, dipoles are formed inside the metal nanoparticles or nanostructures by light entering the nanoparticles or nanostructures to create an electric field around the nanoparticles or nanostructures, and as a result, a plasmonic phenomenon occurs around the nanoparticles or nanostructures, leading to an increase in light absorption.

Many methods have been proposed to utilize such a plasmonic phenomenon of nanoparticles. For example, a method is known in which nanoparticles are mixed in a solution and the mixture is coated on a thin film. According to this method, however, most of the nanoparticles are lost during solution processing, resulting in very low efficiency. Other problems of the method are that it is difficult to control the size and distribution of nanoparticles and a protective film should be used to prevent the nanoparticles from aggregating. Further, a light absorbing layer including the nanoparticles obtained after solution processing is a planar structure, making it difficult to expect further plasmonic effects.

A thin film of nanoparticles may be formed by thermal deposition of a metal in vacuum. In this case, the nanoparticles can be prevented from loss [see A. Yakimov, S. R. Forrest, “High Photovoltage multiple-heterojunction organic solar cells incorporating interfacial metallic nanoclusters”, Appl. Phys. Lett. 80 1667 (2002)]. However, the thickness of the thin film is limited to a few nm or less in order to ensure a sufficient transmittance for incident light. Thus, the size and height of the nanoparticles are limited to a few nm. Due to this dimensional limitation, the size of the nanoparticles and the intervals between the particles cannot be controlled and thus there is a limitation in obtaining optical effects.

Organic photovoltaic cells employing nano-scale periodical structures are undesirable in terms of economic efficiency because complicated exposure or transfer processes through nanostructured masks are required to form the periodical structures.

### SUMMARY OF THE INVENTION

It is one object of the present invention to provide an organic photovoltaic cell whose photovoltaic efficiency is improved by employing a nano-bump structure that enhance plasmonic effects.

It is another object of the present invention to provide a method for fabricating the organic photovoltaic cell.

One aspect of the present invention provides an organic photovoltaic cell including a first electrode layer formed on a substrate, metal nanoparticles bound to the surface of the first electrode layer, a hole transport layer formed on the metal nanoparticles and the exposed portion of the first electrode layer to form a nano-bump structure together with the metal nanoparticles, a photoactive layer formed on the hole transport layer, and a second electrode layer formed on the photoactive layer.

Another aspect of the present invention provides a method for fabricating an organic photovoltaic cell, including forming a first electrode layer on a substrate, binding metal nanoparticles to the surface of the first electrode layer, forming a hole transport layer on the metal nanoparticles and the exposed portion of the first electrode layer to form a nano-bump structure together with the metal nanoparticles, forming a photoactive layer having an uneven structure on the hole transport layer, and forming a second electrode layer on the photoactive layer.

According to one embodiment, the metal nanoparticles are electrically charged and bound in the form of dry aerosols to the surface of the first electrode layer.

The organic photovoltaic cell of the present invention includes metal nanoparticles formed on an electrode and a hole transport layer formed on the metal nanoparticles and the exposed portion of the electrode to form a nano-bump structure together with the metal nanoparticles. Due to the nano-bump structure, plasmonic effects are enhanced, leading to an increase in photocurrent. In addition, the organic photovoltaic cell includes a photoactive layer having an uneven structure. The uneven structure increases the propagation path of light entering the active layer, allowing the active layer to absorb larger amount of the light. As a result, the photovoltaic efficiency of the organic photovoltaic cell can be improved.

According to the method of the present invention, the nano-bump structure can be formed by simple dry aerosol deposition without involving a complicated exposure or transfer process, contributing to a marked improvement in economic efficiency.

### BRIEF DESCRIPTION OF THE DRAWINGS

FIG. 1 is a schematic view illustrating the cross section of an organic photovoltaic cell according to one embodiment of the present invention.

FIG. 2 schematically illustrates a method for fabricating an organic photovoltaic cell according to one embodiment of the present invention.

FIG. 3 is a cross-sectional TEM image of an organic photovoltaic cell structure fabricated in Example 2.

FIGS. 4a, 4b, and 4c are SEM images showing the particle diameter distributions of silver nanoparticles produced in Examples 1, 2, and 3, respectively.

FIG. 5a is a graph showing the voltage-current characteristics of organic photovoltaic cell structures fabricated in Comparative Example 1 and Examples 1 to 3.

FIG. 5b is a graph showing the power conversion efficiencies of organic photovoltaic cell structures fabricated in Comparative Example 1 and Examples 1 to 3.

### DETAILED DESCRIPTION OF THE INVENTION

The present invention will now be described in detail. It should be understood that the terms and words used in the specification and claims are not to be construed as having common and dictionary meanings, but are construed as having meanings and concepts corresponding to the spirit of the invention in view of the principle that the inventor can define properly the concept of the terms and words in order to describe his/her invention with the best method.

According to one embodiment, an organic photovoltaic cell may include a first electrode layer formed on a substrate, metal nanoparticles bound to the surface of the first electrode layer, a hole transport layer formed on the metal nanoparticles and the exposed portion of the first electrode layer to form a nano-bump structure together with the metal nanoparticles, a photoactive layer formed on the hole transport layer, and a second electrode layer formed on the photoactive layer.

The metal nanoparticles are bound to the surface of the first electrode to form nano-bumps. The hole transport layer overlying the metal nanoparticles has a thin film structure and forms a nano-bump structure together with the metal nanoparticles. Due to this construction, dipoles are formed by light entering the nano-bump structure and a plasmonic phenomenon occurs in which the intensity of an electric field increases around the nano-bumps, resulting in an increase in light absorption. The photoactive layer has an uneven structure, which causes a larger proportion of light entering the photovoltaic cell to scatter. Therefore, efficient use of the light is enabled, improving the photovoltaic efficiency of the organic photovoltaic cell employing the nano-bump structure.

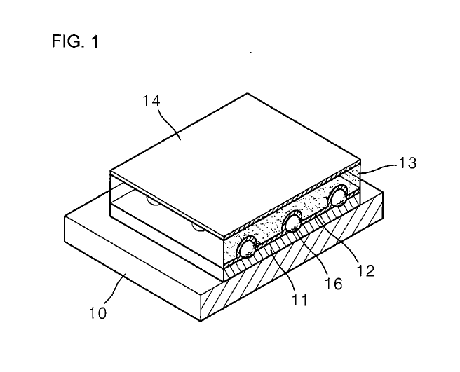

FIG. 1 schematically illustrates the cross section of an organic photovoltaic cell according to one embodiment of the present invention in which a hole transport layer, together with metal nanoparticles, forms a nano-bump structure.

As illustrated in FIG. 1, metal nanoparticles 16 are bound to the surface of at least one surface of a first electrode layer 11 disposed on a substrate 10 to form nano-bumps. A hole transport layer 12 in the form of a thin film is formed on the metal nanoparticles 16 and the exposed portion of the first electrode layer 11. The nano-bump formation allows the hole transport layer 12 to form a nano-bump structure together with the metal nanoparticles. A photoactive layer 13 is formed on the hole transport layer 12 to form a fine uneven structure.

A second electrode layer 14 is formed on the photoactive layer, completing the fabrication of the organic photovoltaic cell 1.

According to one embodiment, the metal nanoparticles 16 bound to the surface of the electrode may be uniformly and randomly distributed on the electrode. Since the metal nanoparticles 16 form nano-bumps on the first electrode layer 11, the hole transport layer 12 overlying the metal nanoparticles 16 does not form a planar structure but forms a partially protruding structure, resulting in the formation of a nano-bump structure together with the metal nanoparticles 16. For example, the nano-bump structure may have a height of about 5 nm to about 100 nm.

There is no particular restriction on the nano-bump structure. The nano-bump structure may refer to a bump structure formed by the metal nanoparticles and the hole transport layer covering the metal nanoparticles.

The photoactive layer 13 is formed along the curved surface of the nano-bump structure to form a fine uneven structure. The uneven structure ensures better light diffusion.

According to one embodiment, the substrate 10 may be made of any transparent material. Examples of such transparent materials include, but are not particularly limited to, glass, polycarbonate, polymethyl (meth) acrylate, polyethylene terephthalate, polyamide, and polyethersulfone.

The first electrode layer 11 and the hole transport layer 12 are opposite electrodes. For example, the first electrode layer 11 and the second electrode layer 14 may be an anode and a cathode, respectively, or vice versa. In the present invention, the first electrode layer 11 is used as an anode and the second electrode layer 14 is used as a cathode.

Examples of materials suitable for the first electrode layer 11 include indium tin oxide (ITO), tin oxide, indium oxide-zinc oxide (IZO), aluminum-doped zinc oxide, gallium-doped zinc oxide, graphene, metal nanowires, and conductive polymers. Indium tin oxide is preferred for its high work function. The first electrode layer 11 may have a thickness of about 10 nm to about 3 μm.

The first electrode layer 11 may be formed on the substrate 10 by any suitable technique known in the art, for example, pulsed laser deposition, sputtering, chemical vapor deposition or ion deposition.

The metal nanoparticles 16 may be in direct contact with and bound to the surface of the first electrode layer 11. The metal nanoparticles 16 may be uniformly and randomly distributed on the first electrode layer 11. For example, the metal nanoparticles may be electrically charged and bound in the form of dry aerosols to the surface of the first electrode layer.

Examples of the metal nanoparticles 16 include, but are not limited to, copper, tin, silver, zinc, platinum, palladium, gold, indium, cadmium, and aluminum nanoparticles.

The metal nanoparticles 16 may be particles of a single metal. Alternatively, the metal nanoparticles 16 may have a core/shell structure in which metal particles as cores are surrounded by shells. In this case, the core particles may be composed of at least one metal selected from the above-mentioned metal materials, for example, copper, tin, silver, zinc, platinum, palladium, gold, indium, cadmium, and aluminum. The shells may be composed of a metal or an insulator. The insulator may be, for example, a metal oxide, a metal nitride, a silicon oxide or a metal sulfide. Examples of such metal oxides include, but are not limited to, molybdenum oxide, vanadium oxide, titanium oxide, and zinc oxide. The size of the metal nanoparticles is not limited. For example, the metal nanoparticles may have a diameter in the range of about 1 nm to about 300 nm or 10 nm to 100 nm. Within this range, plasmonic effects can be induced. The nanoparticles may have any shape that can induce plasmonic effects. For example, the nanoparticles may be spherical in shape. Alternatively, the nanoparticles may have a circular or elliptical shape whose aspect ratio is in the range of 3:1 to 1:3.

As described above, the metal nanoparticles 16 may be uniformly and randomly distributed on the electrode. The surface density of the metal nanoparticles 16 may be in the range of 0.1 to 10.0×10⁹ cm⁻². The intervals between the metal nanoparticles 16 are not particularly limited and may be greater than the diameter of the nanoparticles and smaller than 2 μm.

The hole transport layer 12 may be formed on the metal nanoparticles 16 and the exposed portion of the first electrode layer 11. As the hole transport layer 12, there may be used, for example, a thin film composed of a transparent material that has a high refractive index and can be used as a p-type buffer. For example, the hole transport layer 12 may have a refractive index of at least 2. The hole transport layer 12 in the form of a thin film may have a transmittance of at least 85% or in the range of 85% to 99%.

For example, the hole transport layer 12 may be formed using a tungsten oxide film, a molybdenum oxide film, a vanadium oxide film, a ruthenium oxide film, a nickel oxide film, a chromium oxide film or a combination thereof. The thickness of the hole transport layer 12 may be in the range of 0.1 nm to 50 nm or 1 nm to 30 nm but is not limited to this range. The thickness of the hole transport layer 12 may vary depending on the size of the metal nanoparticles 16. That is, the hole transport layer 12 and the metal nanoparticles 16 form a nano-bump structure and their thicknesses serve as major factors that induce plasmonic effects. Accordingly, plasmonic effects can be controlled by varying the thicknesses of the hole transport layer 12 and the metal nanoparticles 16. Plasmonic effects can be maximized when the thickness of the hole transport layer 12 is in the range of about 0.2 to 4 times, about 0.2 to about 2 times or about 0.5 to about 1.5 times the radius of the metal nanoparticles 16.

The photoactive layer 13 formed on the hole transport layer 12 has a bulk heterojunction (BHJ) structure consisting of a donor region and an acceptor region. Alternatively, the photoactive layer 13 may have a bilayer structure consisting of a donor layer and an acceptor layer. The donor region of the bulk hetero junction structure may contain a p-type semiconductor organic compound as a donor material. For example, the donor material may be a semiconductor polymer based on poly (para-phenylene vinylene), polythiophene or polyfluorene.

The donor material is not limited and more specific examples thereof include poly(3-hexylthiophene) (P3HT), poly[N-9″-heptadecanyl-2,7-carbazole-alt-5,5-(4′,7′-di-2-thienyl-2′,1′,3′-benzothiadiazole)] (PCDTBT), poly[2-methoxy-5-(2′-ethylhexyloxy)-p-phenylene vinylene] (MEH-PPV), poly({4,8-bis[(2-ethylhexyl)oxy]benzo[1,2-b:4,5-b′]dithiophene-2,6-diyl}{3-fluoro-2-[(2-ethylhexyl)carbonyl]thieno[3,4-b]thiophenediyl} (PTB7), poly[1-(6-{4,8-bis[(2-ethylhexyl)oxy]-6-methylbenzo[1,2-b:4,5-b′]dithiophen-2-yl}-3-fluoro-4-methylthieno[3,4-b]thiophen-2-yl)-1-octanone] (PBDTTT-CF), poly[2,6-(4,4-bis-(2-ethylhexyl)-4H-cyclopenta[2,1-b;3,4-b]dithiophene)-alt-4,7(2,1,3-benzothiadiazole)] (PCPDTBT), and poly[2-methoxy-5-(3,7-dimethyloctyloxy)-1-4-phenylene vinylene (MDMOPPV).

The acceptor region may contain an n-type semiconductor organic compound as an acceptor material. Examples of suitable acceptor materials include, but are not limited to, C60, [6,6]-phenyl-C₇₀-butyric acid methyl ester (PC₇₀BM), perylene, 1′,1″,4′,4″-tetrahydro-di[1,4]methanonaphthaleno[1,2:2′,3′,56,60:2″,3″][5,6]fullerene-C60 (ICBA), C60 derivatives, indene-C60 bisadduct, 3,4,9,10-perylene tetracarboxylic bis(benzimidazole) (PTCBI), and dihydropyrrolo[3,4-c]pyrrole (DPP).

The pair of the donor material and the acceptor material constituting the bulk heterojunction structure of the photoactive layer 13 may be, for example, P3HT:PCBM, PCDTBT:PCBM or PTB7:PCBM.

Each of the donor region and the acceptor region may have a domain size in the range of about 5 nm to 30 nm, about 5 nm to about 20 nm or about 10 nm. The domain size in the range defined above is similar to the diffusion distance of excitons, which allows electrons and holes separated from the excitons to efficiently migrate to a cathode and an anode, respectively.

The donor layer of the bilayer structure may include any of the above-mentioned donor materials. Likewise, the acceptor layer may include any of the above-mentioned acceptor materials.

For example, the photoactive layer 13 may have a thickness ranging from about 30 nm to about 2.2 μm. Within this range, the light absorption of the photoactive layer can be increased with efficient charge transfer.

As described above, the photoactive layer 13 having a fine uneven structure is formed on the hole transport layer 12 forming a nano-bump structure together with the metal nanoparticles. As a result, a larger proportion of light entering the photovoltaic cell scatters. This ensures efficient use of the light, contributing to an improvement in photovoltaic efficiency.

The second electrode layer 14 formed on the photoactive layer 13 may be formed using a metal whose work function is lower than that of the first electrode layer 11. The work function of the metal constituting the second electrode layer 14 may be in the range of 4 to 5.5 eV but is not limited to this range. Examples of materials suitable for the second electrode layer 14 include gold (Au), aluminum (Al), calcium (Ca), magnesium (Mg), barium (Ba), molybdenum (Mo), aluminum (A1)-magnesium (Mg), and lithium fluoride (LiF)-aluminum (Al). The thickness of the second electrode layer 14 may be in the range of about 10 nm to about 3 μm but is not limited to this range.

The organic photovoltaic cell may further include an electron transport layer formed between the photoactive layer 13 and the second electrode layer 14. For example, the electron transport layer may be formed using at least one transition metal oxide selected from TiOₓ, ZnO, SnO, Cs₂CO₃, In₂O₃, and SnO₂.

According to one embodiment, a method for fabricating the organic photovoltaic cell may include forming a first electrode layer on a substrate, binding metal nanoparticles to the surface of the first electrode layer, forming a hole transport layer on the metal nanoparticles and the exposed portion of the first electrode layer to form a nano-bump structure together with the metal nanoparticles, forming a photoactive layer having an uneven structure on the hole transport layer, and forming a second electrode layer on the photoactive layer.

According to one embodiment, the method may further include forming an electron transport layer between the photoactive layer and the second electrode layer.

The kinds and formation methods of the substrate, the first electrode layer, the metal nanoparticles, the hole transport layer, the photoactive layer, and the electron transport layer have been described above.

The metal nanoparticles are electrically charged and are then bound in the form of dry aerosols to the surface of the first electrode layer to form nano-bumps. This process facilitates binding of the metal nanoparticles to the first electrode layer without damage to the substrate or the electrode layer.

The metal nanoparticles may be electrically charged by evaporation/condensation and subsequent neutralization through a neutralizer. Alternatively, the charged particles may be produced by spark discharge, arc discharge or electrostatic spray. A precursor material of the charged particles may be selected from the group consisting of metal particles, metal oxides, and mixtures thereof. The evaporation/condensation, spark discharge, arc discharge, and electrostatic spray can be performed by suitable techniques known in the art.

According to one embodiment, the substrate, on which the first electrode layer is formed, is placed in a reactor (a deposition chamber) and a voltage is applied to the electrode using voltage supply means so that the electrode has a polarity opposite to that of the charged nanoparticles.

In the case where spark discharge is used, the nanoparticles are bipolarly charged and ions are generated simultaneously. The nanoparticles and the ions are introduced into a reactor in which the first electrode is present, and an electric field is applied to deposit the nanoparticles on the first electrode irrespective of the polarities of the nanoparticles and the ions. A spark discharge chamber disclosed in Korean Patent Application No. 10-2009-0089787 (published on Aug. 24, 2009) is useful for the production of nanoparticles from various materials. For example, the spark discharge may be performed by applying a voltage of about 1 to about 10 kV, preferably about 4 to about 10 kV. In the case where the spark discharge is performed in combination with corona discharge, a voltage of about 1 to about 10 kV may be applied. A voltage of a polarity opposite to that of the charged particles may be applied to the first electrode. In this case, the voltage may have an intensity of 0.1 to 8 kV.

The size of the metal nanoparticles forming nano-bumps can be adjusted to 1 to 300 nm according to the intended purpose. For spark discharge, the size of the metal nanoparticles is preferably from 1 to 20 nm, most preferably from 3 to 100 nm.

Examples of materials for the nanoparticles include, but are not limited to, metals such as copper, tin, silver, zinc, platinum, palladium, gold, indium, and cadmium.

The binding of the metal nanoparticles to the surface of the electrode by evaporation/condensation will be described in more detail.

First, a metal source is placed in a tube furnace of an evaporation/condensation system equipped with a differential mobility analyzer (DMA), a DMA controller, a neutralizer, a power supply, and a deposition chamber. When the tube furnace is heated, hot metal nanoparticles can be generated. At this time, an inert gas is allowed to flow into the tube furnace to form migration paths of the metal nanoparticles. The hot metal nanoparticles are passed through a cooling water line where the charged particles can be grown by cooling and aggregation. Thereafter, the charged particles are passed through a neutralizer where they are ionized and polydispersed, from which positively charged monodisperse nanoparticles can be separated using the DMA. At this time, various voltages can be applied using the DMA controller according to the electrical mobility of the particles, so that the metal nanoparticles with desired sizes can be obtained. The voltages may be adjusted to, for example, 0.1 to 30 kV.

The average concentration of the charged particles may be controlled before deposition on the electrode. The surface density of the metal nanoparticles on the electrode may be adjusted to a predetermined range by controlling the deposition time.

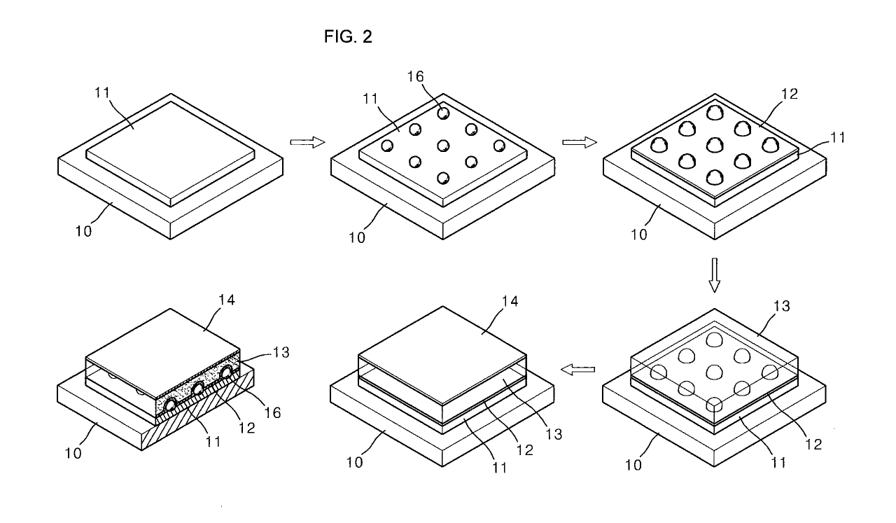

FIG. 2 illustrates an exemplary method for fabricating the organic photovoltaic cell. As illustrated in FIG. 2, an ITO electrode as the first electrode layer 11 is placed on glass as the substrate 10. Silver nanoparticles as the metal nanoparticles 16 are deposited on the first electrode layer 11 by aerosol deposition, as described above. Subsequently, a MoO₃ thin film as the hole transport layer 12 is thermally deposited on the silver nanoparticles, PCDTBT:PC70BM is spin coated on the hole transport layer 12 to form the photoactive layer 13, and LiF/Al is thermally deposited thereon to form the second electrode layer 14. The organic photovoltaic cell structure thus fabricated has a final structure in which the nanoparticles are formed on the ITO and MoO₃ is deposited in the form of a thin film on the silver nanoparticles to form a nano-bump structure together with the silver nanoparticles.

The present invention will be explained in detail with reference to the following examples. However, these examples may be embodied in various different forms and the scope of the invention should not be construed as being limited thereto. The examples are provided to fully convey the invention to a person having ordinary knowledge in the art.

### EXAMPLES

### Examples 1 to 3

ITO was formed to a thickness of 150 nm on a glass substrate having a size of 25 mm×25 mm and a thickness of 0.7 mm by sputtering. Silver nanoparticles were bound to the ITO surface by an evaporation/condensation process using dry aerosols so as to have a size of 20 nm (Example 1). MoO₃ was thermally deposited to a thickness of 20 nm on the silver nanoparticles and the exposed portion of the ITO electrode to form a nano-bump structure together with the silver nanoparticles. Subsequently, a mixture of PCDTBT and PC70BM (weight ratio 1:4) was spin coated to a thickness of 90 nm on the nano-bump structure, and then lithium fluoride (LiF) and aluminum were deposited to thicknesses of 0.5 nm and 100 nm, respectively, thereon to form an electrode, completing the fabrication of an organic photovoltaic cell structure. Organic photovoltaic cell structures were fabricated in the same manner as in Example 1, except that silver nanoparticles had sizes of 40 nm (Example 2) and 60 nm (Example 3).

The evaporation/condensation process using aerosols was carried out by the following procedure.

An evaporation/condensation system was used for the evaporation/condensation process. The evaporation/condensation system included a tube furnace (Okdu SiC tube furnace), a nano-differential mobility analyzer (nano-DMA, TSI 308500), a DMA controller (AERIS), a neutralizer (HCT Aerosol Neutralizer 4530), a high-voltage power supply, two mass flow controllers (MFC, Tylan FC280S), and a deposition chamber in a glove box. First, a silver strip (Alfa aesar) in the form of a solid was placed at one end of a quartz tube located at the center of the tube furnace. Subsequently, the two MFCs were used to supply 99.999% nitrogen gas at a rate of 1.5 liter/min to the quartz tube. When the tube furnace was heated to 1,150° C., silver nanoparticles were generated. The hot silver nanoparticles were passed through a cooling water line at 26° C., where the charged particles were grown by cooling and aggregation. The charged particles were passed through a neutralizer where they were ionized and polydispersed, from which positively charged monodisperse nanoparticles were separated using the nano-DMA and the DMA controller. Different voltages of 1.03, 3.93, and 8.42 kV were applied using the DMA controller according to the electrical mobility of the particles, and as a result, the silver nanoparticles had clearly distinguishable sizes of 20 nm, 40 nm, and 60 nm, respectively. After the average concentration of the charged particles was set to 3.0×10⁵ cm⁻³, the charged particles were deposited on the ITO electrode.

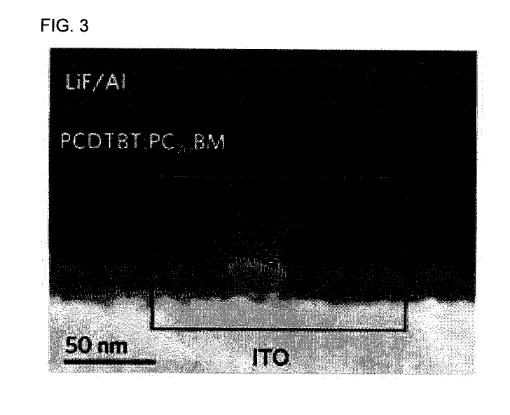

FIG. 3 shows a cross-sectional TEM image of the organic photovoltaic cell structure including the silver nanoparticles with a 40 nm diameter. As shown in FIG. 3, the silver nanoparticles were in direct contact with and bound to the surface of the ITO, and the MoO₃ hole transport layer was formed in the form of a thin film on the nanoparticles and the exposed portion of the ITO electrode to form a nano-bump structure together with the nanoparticles.

### Comparative Example 1

An organic photovoltaic cell structure was fabricated in the same manner as in Example 1, except that silver nanoparticles were not used.

### Experimental Example 1

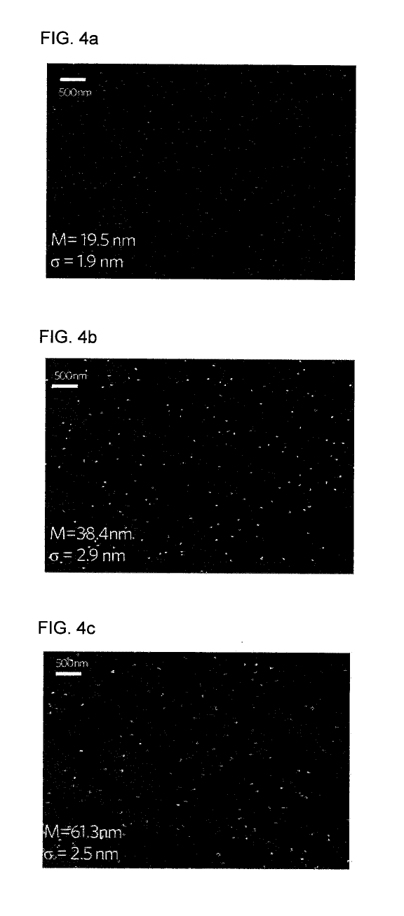

FE-SEM images (×50,000 magnification, analyzed area 6.0 μm×4.2 μm) of the silver nanoparticles with different sizes of 20, 40, and 60 nm are shown in FIGS. 4a, 4b, and 4c, respectively. These images show that the silver nanoparticles with the different sizes were uniformly and randomly dispersed with very small standard deviations. All analyses were performed using the ImageJ software (version 1.46r).

### Experimental Example 2

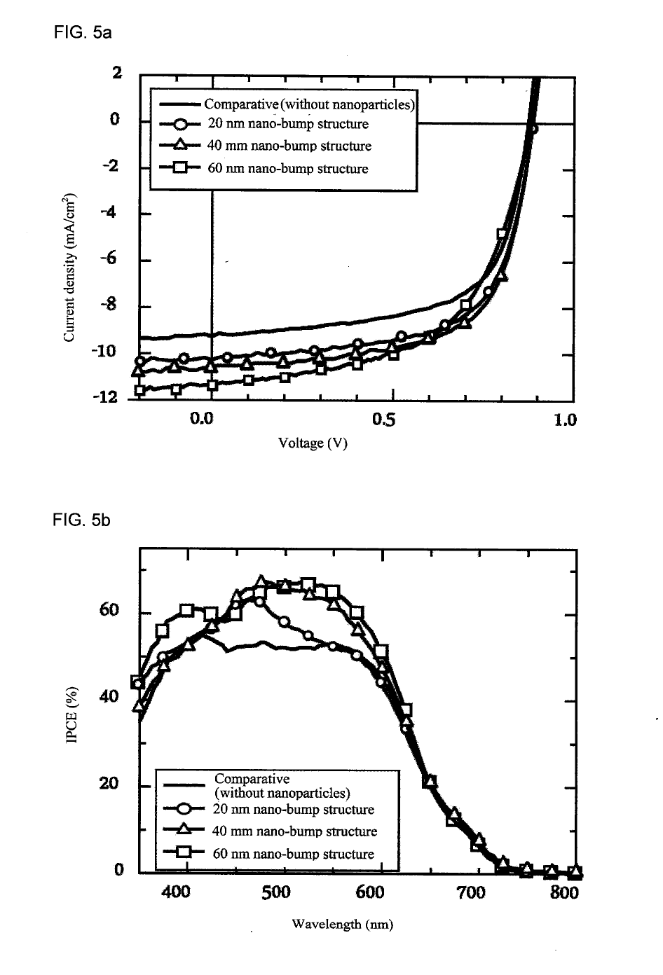

The J-V characteristics and power conversion efficiencies of the structures fabricated in Examples 1, 2, and 3 and Comparative Example 1 were measured under AM 1.5G illumination (100 mW/cm²). The results are shown in FIGS. 5a and 5b and the average values are shown in Table 1.

TABLE 1

| | | | | Power conversion |
|---|---|---|---|---|
| Example No. | J_{SC} (mA/cm²) | V_{OC} (V) | FF | efficiency (%) |
| Comparative | 9.16 | 0.88 | 0.64 | 5.16 |
| Example 1 | | | | |
| Example 1 | 10.15 | 0.88 | 0.65 | 5.80 |
| | (10.8% increase) | | | (12.4% increase) |
| Example 2 | 10.58 | 0.88 | 0.65 | 6.07 |
| | (15.3% increase) | | | (17.6% increase) |
| Example 3 | 11.36 | 0.88 | 0.57 | 5.65 |
| | (24.0% increase) | | | (9.5% increase) |

As can be seen from the results in Table 1 and the graphs of FIGS. 5a and 5b, the power conversion efficiencies of the structures fabricated in Examples 1-3 were higher by about 9.5% to 17.6% than that of the structure fabricated in Comparative Example 1. The higher efficiencies were mainly responsible for the improved short-circuit currents (J_{sc}). These results reveal that the higher efficiencies are attributed to enhanced plasmonic effects induced by the nano-bump structures consisting of the nanoparticles and the overlying nanostructures and enhanced light absorption induced by the uneven structures of the active layers.

What is claimed is:

1. An organic photovoltaic cell comprising
a first electrode layer formed on a substrate,
metal nanoparticles bound to the surface of the first electrode layer to form nano-bumps,
a hole transport layer formed on the metal nanoparticles and the exposed portion of the first electrode layer to form a nano-bump structure together with the metal nanoparticles,
a photoactive layer formed on the hole transport layer, and
a second electrode layer formed on the photoactive layer.

2. The organic photovoltaic cell according to claim 1, wherein an increase in light absorption occurs around the nano-bumps.

3. The organic photovoltaic cell according to claim 1, wherein the photoactive layer has an uneven structure.

4. The organic photovoltaic cell according to claim 1, wherein the nano-bump structure has a height of 5 nm to 100 nm.

5. The organic photovoltaic cell according to claim 1, wherein the first electrode layer is an anode and the second electrode layer is a cathode.

6. The organic photovoltaic cell according to claim 1, wherein the first electrode layer comprises at least one material selected from indium tin oxide (ITO), tin oxide, indium oxide-zinc oxide (IZO), aluminum-doped zinc oxide, gallium-doped zinc oxide, graphene, metal nanowires, and conductive polymers.

7. The organic photovoltaic cell according to claim 1, wherein the metal nanoparticles are selected from copper nanoparticles, tin nanoparticles, silver nanoparticles, zinc nanoparticles, platinum nanoparticles, palladium nanoparticles, gold nanoparticles, indium nanoparticles, cadmium nanoparticles, aluminum nanoparticles, and mixtures thereof.

8. The organic photovoltaic cell according to claim 7, wherein the metal nanoparticles are core/shell structures, the cores are composed of at least one metal selected from copper, tin, silver, zinc, platinum, palladium, gold, indium, cadmium, and aluminum, and the shells are composed of at least one material selected from metals, metal oxides, metal sulfides, silicon oxides, and metal nitrides.

9. The organic photovoltaic cell according to claim 1, wherein the metal nanoparticles have a diameter of 1 nm to 300 nm and an aspect ratio of 3:1 to 1:3.

10. The organic photovoltaic cell according to claim 1, wherein the metal nanoparticles have a surface density of 0.1 to 10.0×10⁹ cm⁻².

11. The organic photovoltaic cell according to claim 1, wherein the intervals between the metal nanoparticles are greater than the diameter of the nanoparticles and smaller than 2 μm.

12. The organic photovoltaic cell according to claim 1, wherein the hole transport layer comprises at least one metal oxide film selected from tungsten, molybdenum, vanadium, ruthenium, nickel, and chromium oxide films.

13. The organic photovoltaic cell according to claim 1, wherein the thickness of the hole transport layer is 0.2 to 2 times the radius of the metal nanoparticles.

14. The organic photovoltaic cell according to claim 1, wherein the photoactive layer has a bulk hetero-j unction structure.

15. The organic photovoltaic cell according to claim 1, further comprising an electron transport layer between the photoactive layer and the second electrode layer.

16. The organic photovoltaic cell according to claim 1, wherein the metal nanoparticles are in direct contact with and bound to the surface of the first electrode layer.

17. A method for fabricating an organic photovoltaic cell, comprising
forming a first electrode layer on a substrate,
binding metal nanoparticles to the surface of the first electrode layer to form nano-bumps,
forming a hole transport layer on the metal nanoparticles and the exposed portion of the first electrode layer to form a nano-bump structure together with the metal nanoparticles,
forming a photoactive layer on the hole transport layer, and
forming a second electrode layer on the photoactive layer.

18. The method according to claim 17, wherein the photoactive layer has an uneven structure.

19. The method according to claim 18, wherein the uneven structure has a height of 5 nm to 100 nm.

20. The method according to claim 17, wherein the metal nanoparticles are electrically charged and bound in the form of dry aerosols to the surface of the first electrode layer.
